(19) United States
(12) Patent Application Publication
(10) Pub. No.: US 2025/0329702 A1
(43) Pub. Date: Oct. 23, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Ming Li, Shanghai (CN)

(73) Assignee: Yibu Semiconductor Co., Ltd., Shanghai (CN)

(21) Appl. No.: 19/187,929

(22) Filed: Apr. 23, 2025

(30) Foreign Application Priority Data
Apr. 23, 2024 (CN) 202410492910.X

(51) Int. Cl. H01L 25/00

(52) U.S. Cl. CPC H01L 25/50

(57) ABSTRACT

The present disclosure relates to a semiconductor packaging method, a semiconductor assembly component and an electronic device in the technical field of semiconductor packaging, in which a first semiconductor device of a first packaged unit is Flip-Chip mounted on a first redistribution layer and is electrically connected to a second redistribution layer through the first redistribution layer and connection structures. A second semiconductor device of a second packaged unit is Flip-Chip mounted on a third redistribution layer and is electrically connected to connection terminals through the third redistribution layer. Stacked interconnection of the first semiconductor device and the second semiconductor device is realized by die-attaching the connection terminals and the second redistribution layer. Thus, no Through Silicon Via processes are needed, reducing the costs for die stacking.

### CROSS-REFERENCE TO RELATED APPLICATION

The present application claims the benefit of priority under the Paris Convention to Chinese Patent Application No. 202410492910.X, filed on Apr. 23, 2024, which is incorporated herein by reference in its entirety.

### TECHNICAL FIELD

The disclosure relates to the field of semiconductor technology, and to a semiconductor packaging method, a semiconductor assembly component and an electronic device.

### BACKGROUND

With the development of electronic products for multiple functions and miniaturization, high density integration of semiconductor package structures is particularly important. Compared with a conventional packaging structure, the Fan-Out type 3D advanced packaging structure uses a flexible three-dimensional packaging technology, wherein an input/output (I/O) interface is independent of the chip size, high-density redistribution is easy to realize in a redistribution layer, resulting in the benefits of improved high-density electrical interconnections between chips.

In advanced 3D packaging, Through Silicon Vias (TSVs) are usually formed in a wafer, and metal is plugged into the through holes. The drawbacks of such processes are higher technological requirements, less mature technology and higher cost.

### SUMMARY

To solve the above technical problems, the present disclosure provides a semiconductor packaging method, a semiconductor assembly component and an electronic device.

In the first aspect, the present disclosure provides a semiconductor packaging method, comprising:

Providing a first packaged unit and a second packaged unit; wherein the first packaged unit comprises a first carrier, a first redistribution layer, first connection structures, a first semiconductor device, a first molding layer and a second redistribution layer; the first redistribution layer is located on one side of the first carrier; the first molding layer is located on one side of the first redistribution layer away from the first carrier; the second redistribution layer is located on one side of the first molding layer away from the first redistribution layer; the first connection structures extend through the first molding layer and is electrically connected to the first redistribution layer and the second redistribution layer; the second packaged unit comprises a third redistribution layer, a second semiconductor device, a second molding layer and first connection terminals, In this embodiment, the second molding layer is located on one side of the third redistribution layer, the second semiconductor device is covered in the second molding layer and is electrically connected to the third redistribution layer, and the first connection terminals are located on one side of the third redistribution layer away from the second molding layer.

Attaching first connection terminals of the second packaged unit to a second redistribution layer of the first packaged unit.

Forming a third molding layer filled in the gaps between the first connection terminals and the second redistribution layer.

Removing the first carrier to expose the first redistribution layer.

Forming second connection terminals on one side of the first redistribution layer away from the first semiconductor device.

In some embodiments, before providing the first packaged unit, the semiconductor packaging method further includes:

Providing a first carrier, and forming the first redistribution layer on one side of the first carrier.

Forming the first connection structures on one side of the first redistribution layer away from the first carrier; the first connection structures are electrically connected to the first redistribution layer.

Providing the first semiconductor device and attaching the active surface of the first semiconductor device to the first redistribution layer.

Forming the first molding layer; the first molding layer covers the first semiconductor device and the first connection structure, and exposes the first connection structures on one side of the first molding layer facing away from the first redistribution layer.

Forming a second redistribution layer on one side of the first molding layer away from the first redistribution layer, wherein the second redistribution layer is electrically connected to the first connection structure.

In some embodiments, the second packaged unit further includes second connection structures and a fourth redistribution layer, where the second connection structures penetrate the second molding layer, the fourth redistribution layer is located on a side of the second molding layer, which faces away from the third redistribution layer, and the fourth redistribution layer is electrically connected to the third redistribution layer through the second connection structure.

The semiconductor packaging method further comprises the following steps before the third molding layer is formed:

Providing the second packaged unit, and attaching the first connection terminals of the second packaged unit to a fourth redistribution layer of the second packaged unit located below the second packaged unit.

In some embodiments, before providing the second packaged unit, the semiconductor packaging method further includes:

Providing a second carrier, and forming the third redistribution layer on one side of the second carrier.

Forming the second connection structures on one side of the third redistribution layer away from the second carrier; the second connection structures are electrically connected to the third redistribution layer.

Providing the second semiconductor device and attaching the active surface of the second semiconductor device to the third redistribution layer.

Forming the second molding layer; the second molding layer covers the second semiconductor device and the second connection structure, and exposes the second connection structures on one side of the second molding layer, which faces away from the third redistribution layer.

Forming a fourth redistribution layer on one side of the second molding layer away from the third redistribution layer, in this embodiment, the fourth redistribution layer is electrically connected to the second connection structure.

Removing the second carrier to expose the third redistribution layer.

Forming the first connection terminals on one side of the third redistribution layer away from the second semiconductor device.

In some embodiments, after forming the second connection terminals on a side of the first redistribution layer facing away from the first semiconductor device, the semiconductor packaging method further includes:

providing a substrate, attaching the substrate to the second connection terminal.

In some embodiments, after attaching the substrate and the second connection terminal, the semiconductor packaging method further includes:

Forming a fourth molding layer; the fourth molding layer is filled in the gaps between the first redistribution layer and the substrate.

In some embodiments, after forming the fourth molding layer, the semiconductor packaging method further includes:

Providing a metal lid, and fixedly covering the metal lid on one side of the substrate facing the first packaged unit; the metal lid comprises a lid plate and a lead frame, In this embodiment, the lid plate and the lead frame form a containing cavity, and the first packaged unit and the second packaged unit are located in the containing cavity.

In some embodiments, after the metal lid is fixedly covered on the side of the substrate facing the first packaged unit, the semiconductor packaging method further includes:

Forming external connection terminals on one side of the substrate away from the second connection terminal.

In the second aspect, the present disclosure also provides a semiconductor assembly component packaged by one of the above-described semiconductor packaging methods.

In the third aspect, the present disclosure also provides an electronic device, including: the semiconductor assembly component.

Compared with prior technology, the technical solution provided by the disclosure has the following advantages:

In the semiconductor packaging method, a first semiconductor device of a first packaged unit is mounted on a first redistribution layer by Flip-Chip process flow and is electrically connected to second redistribution layer through the first redistribution layer and first connection structures; the second semiconductor device of the second packaged unit is inversely mounted on the third redistribution layer by Flip-Chip process flow and is electrically connected to the first connection terminals through the third redistribution layer; attaching the first connection terminals and the second redistribution layer, stacked interconnection of the first semiconductor device and the second semiconductor device is realized, Compared with the Through Silicon Via technology, no needed TSV s process and lower cost.

### BRIEF DESCRIPTION OF THE DRAWINGS

The accompanying drawings, which are incorporated in and constitute a part of this specification, illustrate embodiments consistent with the disclosure and together with the description, explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive efforts.

FIG. 1 is a schematic flowchart of a semiconductor packaging method according to an embodiment of the disclosure.

FIG. 2 is a schematic structural diagram corresponding to various steps of a semiconductor packaging method according to an embodiment of the disclosure.

FIG. 3 is a schematic structural diagram corresponding to various steps of another semiconductor packaging method according to an embodiment of the disclosure.

FIG. 4 is a schematic flowchart of a method for manufacturing a first packaged unit according to an embodiment of the disclosure.

FIG. 5 is a schematic structural diagram corresponding to various steps in the fabrication process of the first packaged unit shown in FIG. 4.

FIG. 6 is a schematic flowchart of a method for manufacturing a second packaged unit according to an embodiment of the disclosure.

FIG. 7 is a schematic structural diagram corresponding to various steps in the fabrication process of the second packaged unit shown in FIG. 6.

FIG. 8 is a schematic structural diagram of a semiconductor device according to an embodiment of the disclosure.

FIG. 9 is a schematic structural diagram of another semiconductor device according to an embodiment of the present disclosure.

FIG. 10 is a schematic structural view of yet another semiconductor device according to an embodiment of the present disclosure.

FIG. 11 is a flowchart illustrating another semiconductor packaging method according to an embodiment of the disclosure.

Components illustrated in the drawings according some embodiments include: a first packaged unit 1; a first redistribution layer 11; a first molding layer 12; a first semiconductor device 13; first connection structures 14; a second redistribution layer 15; a second packaged unit 2; a third redistribution layer 21; a second molding layer 22; a second semiconductor device 23; second connection structures 24; a fourth redistribution layer 25; first connection terminals 26; a first carrier 31; a second carrier 32; a third carrier 33; a third molding layer 4; a second connection terminals 5; a substrate 6; a fourth molding layer 7; a metal lid 8; a lid plate 81; a lead frame 82; external connection terminals 9.

### DETAILED DESCRIPTION OF THE EMBODIMENTS

In order that the above objects, features and advantages of the present disclosure may be more clearly understood, further description of aspects of the present disclosure will be provided below. It should be noted that, without conflict, the embodiments of the present disclosure and features in the embodiments may be combined with each other.

In the following description, numerous specific details are set forth to provide a thorough understanding of the present disclosure, but the present disclosure may be practiced otherwise than as described herein; it will be apparent that the embodiments in the specification are only some, but not all, embodiments of the disclosure.

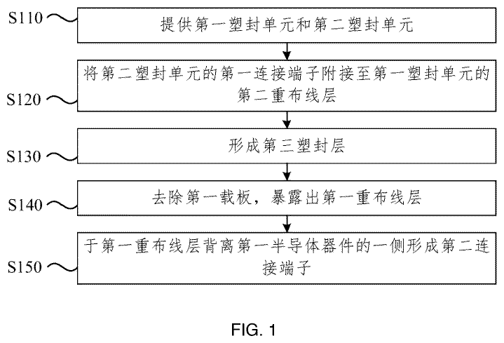

The following describes exemplary semiconductor packaging methods, semiconductor components, and electronic devices according to embodiments of the present disclosure with reference to FIGS. 1 to 11.

In some embodiments, as shown in FIG. 1, a semiconductor packaging method is provided in an embodiment of the disclosure. Referring to FIG. 1, the semiconductor packaging method includes steps S110, S120, S130, S140, and S150, as described below.

S110, providing a first packaged unit and a second packaged unit.

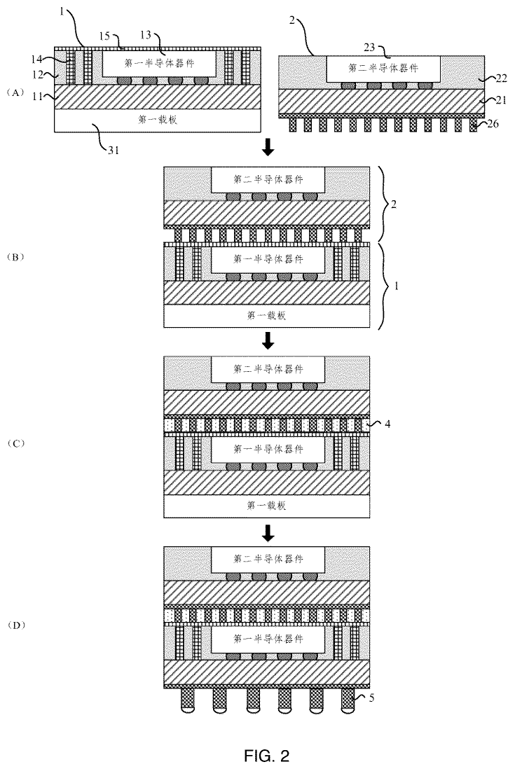

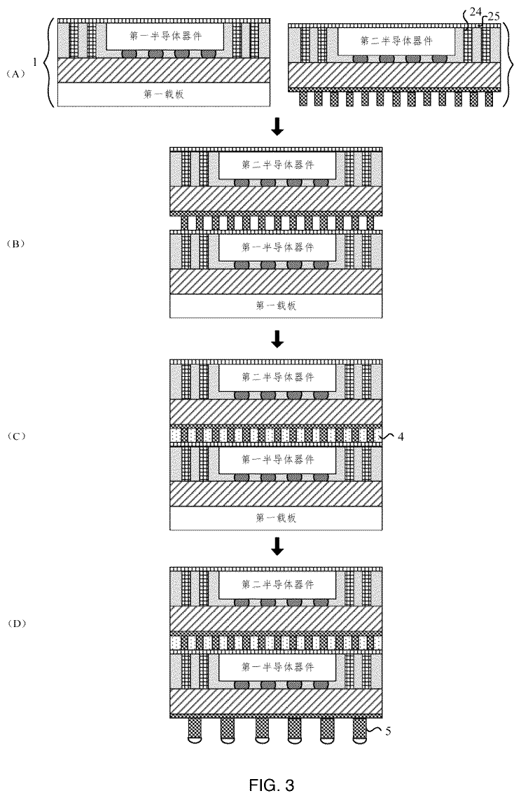

Referring to Part (A) in FIG. 2 or 3, the first packaged unit 1 includes a first carrier 31, a first redistribution layer 11, first connection structures 14, a first semiconductor device 13, a first molding layer 12 and a second redistribution layer 15, the first redistribution layer 11 is located on one side of the first carrier 31, the first molding layer 12 is located on one side of the first redistribution layer 11 facing away from the first carrier 31, the second redistribution layer 15 is located on one side of the first molding layer 12 facing away from the first redistribution layer 11, the first connection structures 14 penetrate the first molding layer 12 and are electrically connected to the first redistribution layer 11 and the second redistribution layer 15, and the first semiconductor device 13 is covered in the first molding layer 12 and is electrically connected to the first redistribution layer 11.

The second packaged unit 2 comprises a third redistribution layer 21, a second semiconductor device 23, a second molding layer 22 and first connection terminals 26, the second molding layer 22 is located on one side of the third redistribution layer 21, the second semiconductor device 23 is covered in the second molding layer 22 and electrically connected to the third redistribution layer 21, and the first connection terminals 26 are located on one side of the third redistribution layer 21 away from the second molding layer 22.

In some embodiments, semiconductor devices include, but are not limited to, wafers, dies, and chips, and also include all types of semiconductor devices known to those skilled in the technology, and are not described in further detail thereto. The semiconductor device includes oppositely disposed passive and active surfaces, the active surface including connection terminals including bumps and/or pads. The semiconductor device includes a first semiconductor device 13 and a second semiconductor device 23, the first semiconductor device 13 being packaged in the first packaged unit 1, the second semiconductor device being packaged in the second packaged unit 2. The connection terminals of the active surface of the first semiconductor device 13 is attached to the first redistribution layer 11, and is electrically connected to the first redistribution layer 11. The connection terminals of the active surface of the second semiconductor device 23 is attached to the third redistribution layer 21, and is electrically connected to the third redistribution layer 21.

It should be noted that the types and numbers of the first semiconductor devices 13 and the second semiconductor devices 23 are not described in further detail in the embodiments of the present disclosure, the types of the first semiconductor devices 13 and the second semiconductor devices 23 may be the same or different, and the first packaged unit 1 includes one or more first semiconductor devices 13, and the second packaged unit 2 includes one or more second semiconductor devices 23, which is not described in further detail herein.

The first redistribution layer 11, the first connection structures 14, the second redistribution layer 15, the third redistribution layer 21, and the first connection terminals 26 are each made of a conductive material, such as at least one of copper, aluminum, silver, gold, and titanium. The first redistribution layer 11, the first connection structures 14, the second redistribution layer 15, the third redistribution layer 21, and the first connection terminals 26 may be made of the same material or different materials, and are not described in further detail herein. The materials from which the first and second molding layers 12, 22 are made include molding compounds of a resinous material, such as an epoxy resin.

The semiconductor device includes a high-power chip having a large area, and the area is 600 mm².

S120, attaching the first connection terminals of the second packaged unit to the second redistribution layer of the first packaged unit.

In connection with step (B) in FIG. 2 or 3, the first packaged unit 1 and the second packaged unit 2 are stacked, the first connection terminals 26 of the second packaged unit 2 faces the second redistribution layer 15 of the first packaged unit 1, and the first connection terminals 26 are electrically connected to the second redistribution layer 15, and the second semiconductor device 23 and the first semiconductor device 13 are interconnected through the third redistribution layer 21, the first connection terminals 26, the second redistribution layer 15, the first connection structures 14, and the first redistribution layer 11.

S130, forming a third molding layer.

In connection with step (C) of FIG. 2 or 3, a molding material is filled in the gap between the first connection terminals 26 and the second redistribution layer 15, and after curing, a third molding layer 4 is formed to protect and reinforce the connection of the first packaged unit 1 and the second packaged unit 2.

S140, removing the first carrier to expose the first redistribution layer.

S150, forming a second connection terminals on one side of the first redistribution layer away from the first semiconductor device.

In connection with step (D) in FIG. 2 or 3, the first carrier 31 may be removed by using all the de-bonding processes known to those skilled in the technology, such as laser de-bonding, thermal de-bonding, or mechanical de-bonding, which are not described in further detail herein. After the first carrier 31 is removed, a surface of the first redistribution layer 11 facing away from the first semiconductor device 13 is exposed, and a second connection terminals 5 are formed on a side of the first redistribution layer 11 facing away from the first semiconductor device 13, where the second connection terminals 5 are electrically connected to the first redistribution layer 11. The second connection terminals 5 are used for connecting other electronic devices, such as a substrate or a printed circuit board.

The second packaged unit 2 shown in FIG. 2 includes a third redistribution layer 21, a second semiconductor device 23, and a second molding layer 22, and only the second packaged unit 2 can be stacked above the first packaged unit 1. The second packaged unit 2 shown in FIG. 3 further comprises second connection structures 24 and a fourth redistribution layer 25, and at least two second packaged units 2 can be stacked above the first packaged unit 1.

In the semiconductor packaging method provided by the embodiment of the disclosure, the first semiconductor device 13 of the first packaged unit 1 is Flip-Chip mounted on the first redistribution layer 11 and is electrically connected with the second redistribution layer 15 through the first redistribution layer 11 and the first connection structures 14; the second semiconductor device 23 of the second packaged unit 2 is Flip-Chip mounted on the third redistribution layer 21 and is electrically connected to the first connection terminals 26 through the third redistribution layer 21; by the attachment of the first connection terminals 26 and the second redistribution layer 15, a stacked interconnection of the first semiconductor device 13 and the second semiconductor device 23 is realized, Compared with the Through Silicon Via technology, no needed TSV s process and lower cost.

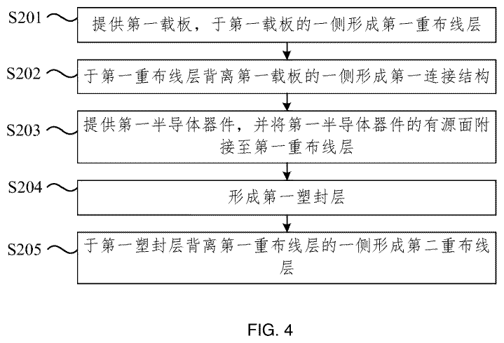

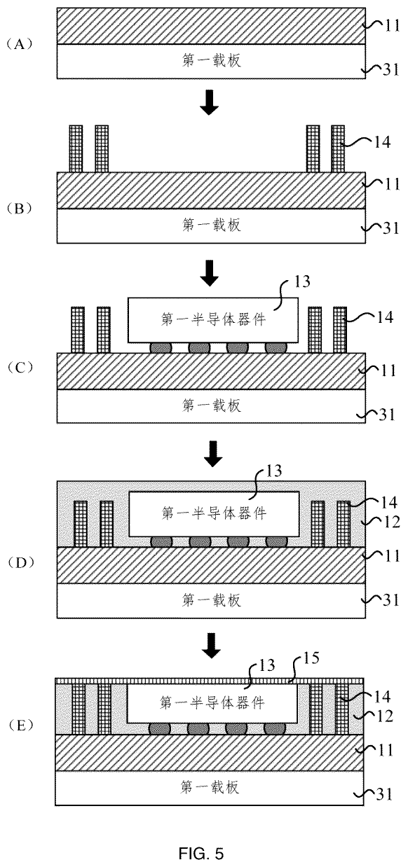

In some embodiments, as shown in FIG. 4, before the “providing the first packaged unit”, the semiconductor packaging method further includes steps S201, S202, S203, S204, and S205, as described below with reference to FIG. 5.

S201, providing a first carrier, and forming a first redistribution layer on one side of the first carrier.

As shown in step (A) of FIG. 5, the first redistribution layer 11 is located on one side of the first carrier 31. The first redistribution layer 11 includes a metal layer and an insulating layer, and the number of layers of the metal layer and the insulating layer is not described in further detail in the embodiment of the present disclosure.

The presently disclosed embodiments employ techniques known in the technology for preparing the first redistribution layer 11. Illustratively, the first redistribution layer 11 is prepared by: a release layer, a seed layer and an insulating layer are sequentially formed on one side surface of the first carrier 31, a patterned via hole is formed in the first insulating layer by using a photolithography or etching process, the via hole is in the shape of a metal layer, and a metal layer is formed in the via hole by using a sputtering or electroplating process. In the case where a plurality of metal layers is included in the first redistribution layer 11, the above steps may be repeated until all the metal layers and all the insulating layers of the first redistribution layer 11 are formed.

In some embodiments, after the preparation of the first redistribution layer 11 is completed, the electrical conductivity of the first redistribution layer 11 may be tested, and the subsequent steps may be performed after the test is qualified, which is beneficial to improving the product yield and reducing the manufacturing cost.

S202, first connection structures is formed on one side of the first redistribution layer away from the first carrier.

As shown in step (B) of FIG. 5, the first connection structures 14 are electrically connected to the first redistribution layer 11. The first connection structures 14 are prepared by: and coating photoresist on one side of the first redistribution layer 11, which is away from the first carrier 31, exposing and developing the photoresist to obtain openings corresponding, respectively, to the first connection structures 14, exposing the first redistribution layer 11 at the bottom of the opening, forming the first connection structures 14 in the openings by adopting an electroplating process, and removing the photoresist. The material of the first connection structures 14 may be the same as that of the metal layer in the first redistribution layer 11, for example, both of them are copper.

S203, providing a first semiconductor device, and attaching an active surface of the first semiconductor device to the first redistribution layer.

As shown in step (C) of FIG. 5, the connection terminals of the first semiconductor device 13 is oriented toward the first redistribution layer 11, and the connection terminals are electrically connected to the first redistribution layer 11 by a soldering process. The first connection structures 14 are located on at least one side of the first semiconductor device 13.

S204, forming a first molding layer.

As shown in step (D) of FIG. 5, the first molding layer 12 encapsulates the first semiconductor device 13 and the first connection structures 14, and also covers the unoccupied surface of the first redistribution layer 11. Then, as shown in step (E) of FIG. 5, the first molding layer 12 is thinned by grinding or etching process until the first connection structures 14 are exposed from the surface of the side of the first molding layer 12 facing away from the first redistribution layer 11.

S205, forming a second redistribution layer on one side of the first molding layer away from the first redistribution layer.

As shown in step (E) of FIG. 5, a second redistribution layer 15 is formed on a surface of the first molding layer 12 facing away from the first redistribution layer 11, and the second redistribution layer 15 is electrically connected to the first connection structures 14, that is, the second redistribution layer 15 and the first redistribution layer 11 are electrically connected through the first conductive structure 14. The fabrication process of the second redistribution layer 15 is similar to that of the first redistribution layer 11, and will not be described here.

In some embodiments, as shown in FIG. 3 or 8, the second packaged unit 2 further includes second connection structures 24 and a fourth redistribution layer 25, where the second connection structures 24 penetrate the second molding layer 22, and the fourth redistribution layer 25 is located on a side of the second molding layer 22 facing away from the third redistribution layer 21, and the fourth redistribution layer 25 is electrically connected to the third redistribution layer 21 through the second connection structures 24.

The semiconductor packaging method further comprises the following steps before the third molding layer is formed:

Providing a second packaged unit, and attaching the first connection terminals of the second packaged unit to a fourth redistribution layer of the second packaged unit located below the second packaged unit.

In this embodiment, as shown in FIG. 8, at least two of the second packaged units 2 may be stacked above the first packaged unit 1. The adjacent two of the second packaged units 2 attach the first connection terminals 26 of the second packaged unit 2 located above with the fourth redistribution layer 25 of the second packaged unit 2 located below, so that the second packaged unit 2 located above is electrically connected with the second packaged unit 2 and the first packaged unit 1 located below.

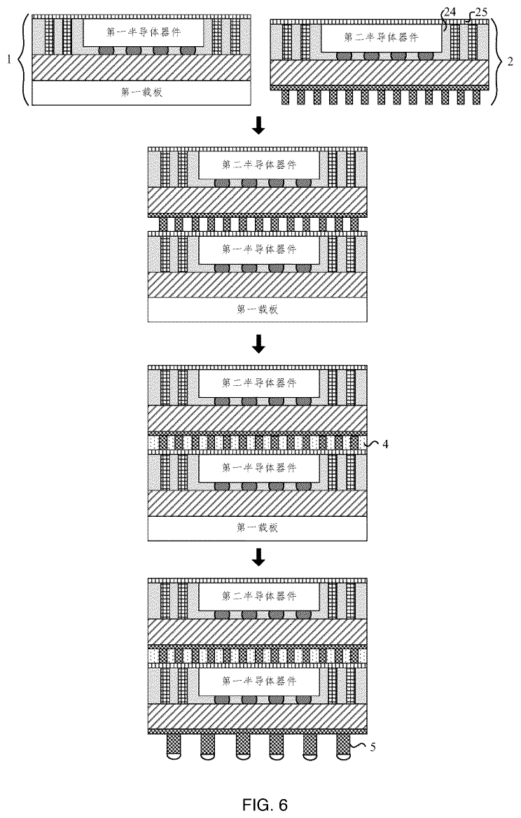

In some embodiments, as shown in FIG. 6, before the “providing the second packaged unit”, the semiconductor packaging method further includes steps S301, S302, S303, S304, S305, S306, and S307, as described below.

S301, providing a second carrier, and forming a third redistribution layer on one side of the second carrier.

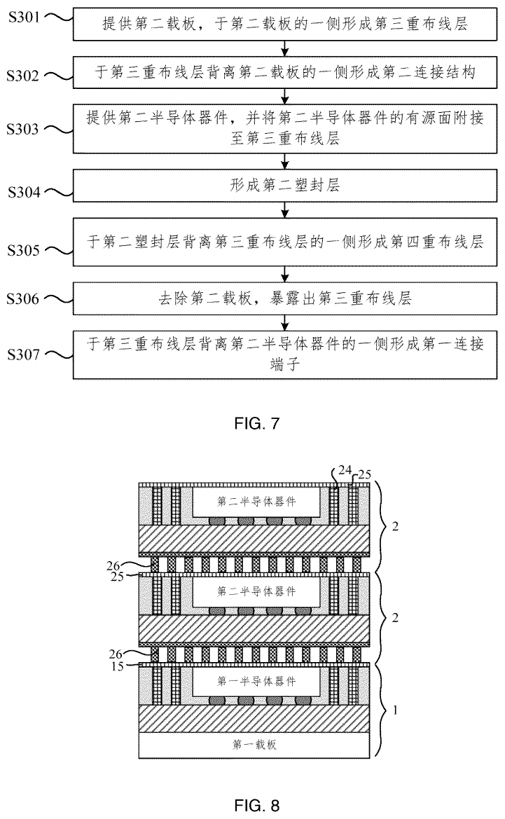

As shown in step (A) of FIG. 7, the third redistribution layer 21 is located on one side of the second carrier 32. The third redistribution layer 21 includes a metal layer and an insulating layer, and the number of layers of the metal layer and the insulating layer is not described in further detail in the embodiment of the present disclosure. The fabrication process of the third redistribution layer 21 is the same as the fabrication process of the first redistribution layer 11, and will not be described here again.

S302, forming second connection structures on one side of the third redistribution layer away from the second carrier.

In this embodiment, the second connection structures are electrically connected to the third redistribution layer.

As shown in step (B) of FIG. 7, the second connection structures 24 are electrically connected to the third redistribution layer 21. Fabrication process of the second connection structures 24 the fabrication process of the first connection structures 14 is the same and will not be described here again. The material of the second connection structures 24 may be the same as that of the metal layer in the third redistribution layer 21, for example, both of them are copper.

S303, providing a second semiconductor device, and attaching an active surface of the second semiconductor device to the third redistribution layer.

As shown in step (C) of FIG. 7, the connection terminals of the second semiconductor device 23 is directed to the third redistribution layer 21, and the connection terminals are electrically connected to the third redistribution layer 21 by a soldering process. The second connection structures 24 are located on at least one side of the second semiconductor device 23.

S304, forming a second molding layer.

The second molding layer covers the second semiconductor device and the second connection structure, and exposes the second connection structures on one side of the second molding layer, which faces away from the third redistribution layer.

As shown in step (D) of FIG. 7, the second molding layer 22 covers the second semiconductor device 23 and the second connection structures 24, and also covers the unoccupied surface of the third redistribution layer 21. Then, as shown in step (E) of FIG. 7, the second molding layer 22 is thinned by grinding or etching process until the second connection structures 24 are exposed from the surface of the second molding layer 22 facing away from the third redistribution layer 21.

S305, forming a fourth redistribution layer on one side of the second molding layer away from the third redistribution layer.

As shown in step (E) of FIG. 7, a fourth redistribution layer 25 is formed on a surface of the second molding layer 22 facing away from the third redistribution layer 21, and the fourth redistribution layer 25 is electrically connected to the second connection structures 24, that is, the fourth redistribution layer 25 and the third redistribution layer 21 are electrically connected through the second conductive structure 24. The fabrication process of the fourth redistribution layer 25 is similar to that of the first redistribution layer 11, and will not be described here again.

S306, removing the second carrier to expose the third redistribution layer.

As shown in step (F) of FIG. 7, a third carrier 33 is provided, and the third carrier 33 is attached to the side of the fourth redistribution layer 25 facing away from the second molding layer 22; then, as shown in step (G) of FIG. 7, the second carrier 32 is removed by at least one of laser bonding, thermal bonding and mechanical bonding, exposing a side surface of the third redistribution layer 21 facing away from the second semiconductor device 23.

S307, forming first connection terminals on a side of the third redistribution layer facing away from the second semiconductor device.

As shown in step (F) of FIG. 7, first connection terminals 26 are formed on a side of the third redistribution layer 21 facing away from the second semiconductor device 23, the first connection terminals 26 being electrically connected to the third redistribution layer 21.

In some embodiments, after “forming the second connection terminals on a side of the first redistribution layer facing away from the first semiconductor device”, the semiconductor packaging method further includes the steps of:

Providing a substrate and attaching the substrate to the second connection terminal.

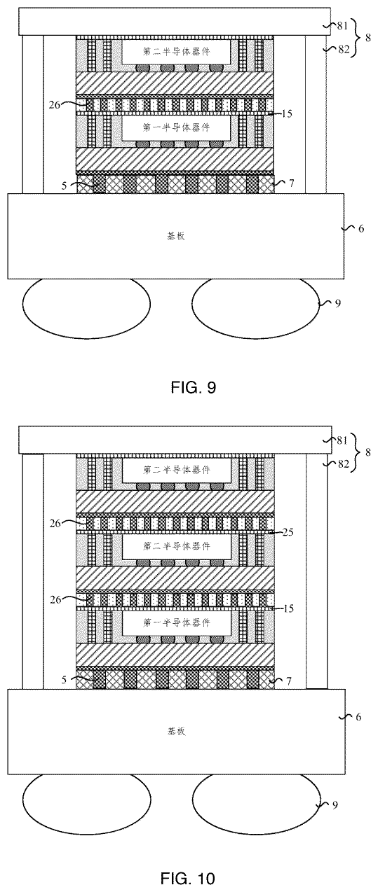

As shown in FIG. 9 or 10, the substrate 6 includes an Ajinomoto Build-up Film (ABF) substrate and a bismaleimide/triazo well resin (Bismaleimide Triazine, BT) substrate.

In some embodiments, after “attach substrate to second connection terminal”, the semiconductor packaging method further includes the steps of:

Forming a fourth molding layer.

As shown in FIG. 9 or 10, the fourth molding layer 7 fills in the gap between the first redistribution layer 11 and the substrate 6. The fourth molding layer 7 may be a prepreg, which is used to cover the second connection terminals 5, and the prepreg includes one or more of epoxy resin, polyethylene, polypropylene, polyolefin, polyamide, polyurethane, and the like. The fourth molding layer 7 may be made of liquid or powder epoxy resin, and not only covers the second connection terminals 5, but also fills the gaps between the second connection terminals 5.

In some embodiments, after “forming the fourth molding layer”, the semiconductor packaging method further comprises:

Providing a metal lid, and fixedly covering the metal lid on one side of the substrate facing the first packaged unit.

As shown in FIG. 9 or 10, the metal lid 8 includes a lid plate 81 and a frame 82, and the lid plate 81 and the frame 82 form a receiving chamber having an opening. In this step, the opening of the metal lid 8 faces the substrate 6, the frame 82 is fixedly connected with the substrate 6, the first packaged unit 1 and the second packaged unit 2 are located in the accommodating cavity, and the metal lid 8 is used for protecting the first packaged unit 1 and the second packaged unit 2 and also for dissipating heat.

In some embodiments, after the metal lid is fixedly covered on the side of the substrate facing the first packaged unit, the semiconductor packaging method further includes the following steps:

Forming external connection terminals on one side of the substrate away from the second connection terminal.

In this embodiment, the substrate 6 is provided with a through hole penetrating through the thickness thereof, and the through hole is filled with conductive material, so that the second connection terminals 5 located above the substrate 6 is electrically connected to the external connection terminals 9 located below the substrate 6. The external connection terminals 9 are used for connecting external devices such as a printed circuit board or a power supply.

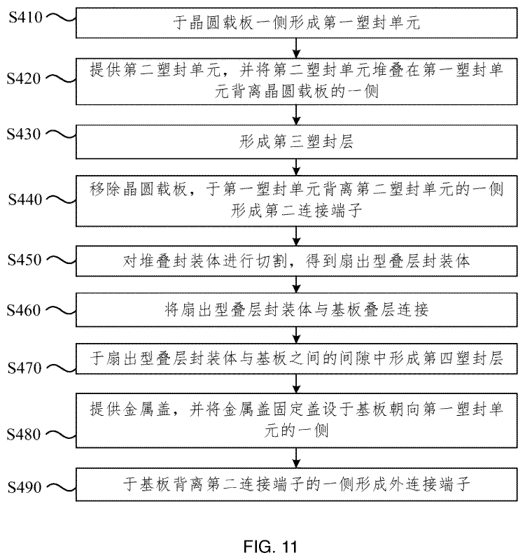

In some embodiments, as shown in FIG. 11, the semiconductor packaging method includes steps S410, S420, S430, S440, S450, S460, S470, S480, and S490, as described below.

S410, forming a first packaged unit on one side of the wafer carrier.

In this embodiment, referring to FIG. 5, the first packaged unit 1 includes a first carrier 31, a first redistribution layer 11, first connection structures 14, a first semiconductor device 13, a first molding layer 12 and a second redistribution layer 15, the first redistribution layer 11 is located on one side of the first carrier 31, the first molding layer 12 is located on one side of the first redistribution layer 11 facing away from the first carrier 31, the second redistribution layer 15 is located on one side of the first molding layer 12 facing away from the first redistribution layer 11, the first connection structures 14 penetrate the first molding layer 12 and is electrically connected with the first redistribution layer 11 and the second redistribution layer 15, and the first semiconductor device 13 is covered in the first molding layer 12 and is electrically connected with the first redistribution layer 11.

S420, providing a second packaged unit, and stacking the second packaged unit on one side of the first packaged unit away from the wafer carrier.

In this embodiment,, referring to FIG. 6 or 8, the second packaged unit 2 includes a third redistribution layer 21, a second semiconductor device 23, a second molding layer 22, first connection terminals 26, second connection structures 24, and a fourth redistribution layer 25, the second molding layer 22 is located at one side of the third redistribution layer 21, the second semiconductor device 23 is covered in the second molding layer 22 and electrically connected with the third redistribution layer 21, the first connection terminals 26 are located at one side of the third redistribution layer 21 facing away from the second molding layer 22, the second connection structures 24 penetrate the second molding layer 22, the fourth redistribution layer 25 is located at one side of the second molding layer 22 facing away from the third redistribution layer 21, and the fourth redistribution layer 25 is electrically connected with the third redistribution layer 21 through the second connection structures 24.

In this step, the second packaged unit 2 may be stacked over the first packaged unit 1 in a single or whole wafer manner. The number of layers of the second packaged unit 2 stacked above the first packaged unit 1 is greater than or equal to one layer. S430, forming a third molding layer.

The step is the same as S130, and the explanation of S130 is omitted here.

S440, removing the wafer carrier, and forming a second connection terminals on one side of the first packaged unit away from the second packaged unit.

The step is the same as S140, and the explanation of S140 is omitted here.

S450, sawing the stacked package to obtain the Fan-out type stacked package.

After the second connection terminals 5 are formed, the resulting stacked package saw S440 into a plurality of Fan-Out type stacked packages.

S460, connecting the Fan-Out type stacked package with the substrate lamination.

In this step, referring to FIG. 9 or 10, the second connection terminals 5 of the Fan-Out type stack package is directed to the substrate 6, and the second connection terminals 5 are attached to one side surface of the substrate 6.

S470, forming a fourth molding layer in the gaps between the Fan-Out type stacked package and the substrate.

And S480, providing a metal lid, and fixedly covering the metal lid on one side of the substrate facing away from the first packaged unit.

And S490, forming external connection terminals on one side of the substrate away from the second connection terminal.

In this embodiment, the external connection terminals 9 is electrically connected to the second connection terminals 5 through the substrate 6. On the basis of the foregoing embodiments, the embodiments of the present disclosure further provide a semiconductor assembly component, where the semiconductor assembly component is packaged by any one of the foregoing semiconductor packaging methods, and has corresponding beneficial effects, and in order to avoid repetitive description, no further description is given here.

On the basis of the foregoing implementation manner, the embodiments of the present disclosure further provide an electronic device, which includes the semiconductor component and has corresponding beneficial effects, and to avoid repeated description, the description is not presented herein.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” “include,” or any other variation thereof, are intended to cover a non-exclusive inclusion, such that a process, method, material, or equipment that comprises a list of elements does not include only those elements but may include other elements not expressly listed or inherent to such process, method, material, or equipment. Without further limitation, an element defined by the phrase “comprising one . . . ” does not exclude the presence of other like elements in a process, method, material, or equipment that comprises the element.

The foregoing are merely specific embodiments of the disclosure to enable one skilled in technology to understand or practice the disclosure. Various modifications to these embodiments will be readily apparent to those skilled in technology, and the generic principles defined herein may be applied to other embodiments without departing from the spirit or scope of the disclosure. Thus, the present disclosure is not intended to be limited to the embodiments shown and described herein but is to be accorded with the widest scope consistent with the principles and novel features disclosed herein.

What is claimed is:

1. A semiconductor packaging method, comprising:
providing a first packaged unit and a second packaged unit, wherein:
the first packaged unit comprises a first carrier, a first redistribution layer, first connection structures, a first semiconductor device, a first molding layer and a second redistribution layer;
the first redistribution layer is located on one side of the first carrier; the first molding layer is located on one side of the first redistribution layer away from the first carrier;
the second redistribution layer is located on one side of the first molding layer away from the first redistribution layer;
the first connection structures extend through the first molding layer and are electrically connected to the first redistribution layer and the second redistribution layer;
the second packaged unit comprises a third redistribution layer, a second semiconductor device, a second molding layer and first connection terminals;
the second molding layer is located on one side of the third redistribution layer; the second semiconductor device is covered in the second molding layer and is electrically connected to the third redistribution layer; and
the first connection terminals are located on one side of the third redistribution layer away from the second molding layer;
attaching the first connection terminals of the second packaged unit to the second redistribution layer of the first packaged unit;
forming a third molding layer in the gaps between the first connection terminals and the second redistribution layer;
removing the first carrier to expose the first redistribution layer; and
forming second connection terminals on one side of the first redistribution layer away from the first semiconductor device.

2. The semiconductor packaging method of claim 1, further comprising, before providing the first packaged unit:
providing a first carrier, and forming the first redistribution layer on one side of the first carrier;
forming the first connection structures on one side of the first redistribution layer away from the first carrier, wherein the first connection structures are electrically connected to the first redistribution layer;
providing the first semiconductor device and attaching the active surface of the first semiconductor device to the first redistribution layer;
forming the first molding layer; the first molding layer embeds the first semiconductor device and the first connection structures and exposes ends of the first connection structure on one side of the first molding layer facing away from the first redistribution layer; and
forming the second redistribution layer on one side of the first molding layer away from the first redistribution layer, wherein the second redistribution layer is electrically connected to the first connection structures.

3. The semiconductor packaging method of claim 1, wherein the second packaged unit further comprises second connection structures and a fourth redistribution layer, the second connection structures extend through the second molding layer, the fourth redistribution layer is located on one side of the second molding layer away from the third redistribution layer; and the fourth redistribution layer is electrically connected to the third redistribution layer through the second connection structure;
the semiconductor packaging method further comprising, before forming the third molding layer:
providing the second packaged unit, and attaching the first connection terminals of the second packaged unit to a fourth redistribution layer of the second packaged unit located below the second packaged unit.

4. The semiconductor packaging method of claim 3, further comprising, before providing the second packaged unit:
providing a second carrier, and forming the third redistribution layer on one side of the second carrier;
forming the second connection structures on one side of the third redistribution layer away from the second carrier, wherein the second connection structures are electrically connected to the third redistribution layer;
providing the second semiconductor device and attaching the active surface of the second semiconductor device to the third redistribution layer;
forming the second molding layer; the second molding layer covers the second semiconductor device and the second connection structure, and exposes the second connection structures on one side of the second molding layer, which faces away from the third redistribution layer;
forming a fourth redistribution layer on one side of the second molding layer away from the third redistribution layer; wherein, the fourth redistribution layer is electrically connected to the second connection structure;
removing the second carrier to expose the third redistribution layer; and
forming the first connection terminals on one side of the third redistribution layer away from the second semiconductor device.

5. The semiconductor packaging method according to claim 1, further comprising, after forming a second connection terminals on a side of the first redistribution layer facing away from the first semiconductor device:
providing a substrate, attaching the substrate to the second connection terminal.

6. The semiconductor packaging method of claim 5, further comprising, after attaching the substrate and the second connection terminal:
forming a fourth molding layer; the fourth molding layer in the gaps between the first redistribution layer and the substrate.

7. The semiconductor packaging method of claim 6, further comprising, after forming the fourth molding layer:
providing a metal lid, and fixedly covering the metal lid on one side of the substrate facing away from the first packaged unit; wherein the metal lid comprises a lid plate and a lead frame, the lid plate and the lead frame form a cavity, and the first packaged unit and the second packaged unit are positioned in the cavity.

8. The semiconductor packaging method of claim 7, further comprising, after a metal lid is fixedly provided on a side of the substrate facing the first packaged unit:
forming external connection terminals on one side of the substrate away from the second connection terminal.

9. A semiconductor assembly component, packaged using the semiconductor packaging method according to claim 1.

10. An electronic device, comprising the semiconductor assembly component of claim 9.

11. A semiconductor packaging method, comprising:
forming a first packaged unit, including:
forming a first redistribution layer on one side of a first carrier;
forming the first connection structures on one side of the first redistribution layer away from the first carrier, wherein the first connection structures are electrically connected to the first redistribution layer;
flip-chip mounting a first semiconductor device onto the first redistribution layer;
forming a first molding layer, wherein the first molding layer embeds the first semiconductor device and the first connection structures and exposes ends of the first connection structures on one side of the first molding layer facing away from the first redistribution layer; and
forming a second redistribution layer on one side of the first molding layer, away from the first redistribution layer, wherein the second redistribution layer is electrically connected to the first connection structures;
forming a second packaged unit, including:
forming a third redistribution layer on one side of a second carrier;
forming second connection structures on one side of the third redistribution layer away from the second carrier, wherein the second connection structures are electrically connected to the third redistribution layer;
flip-chip mounting a second semiconductor device onto to the third redistribution layer;
forming a second molding layer, wherein the second molding layer embeds the second semiconductor device and the second connection structures, and exposes ends of the second connection structures on one side of the second molding layer away from the third redistribution layer;
forming a fourth redistribution layer on one side of the second molding layer away from the third redistribution layer wherein the fourth redistribution layer is electrically connected to the second connection structure;
removing the second carrier to expose the third redistribution layer; and
forming first connection terminals on one side of the third redistribution layer away from the second semiconductor device;
attaching the first connection terminals of the second packaged unit to the second redistribution layer of the first packaged unit;
forming a third molding layer in the gaps between the first connection terminals and the second redistribution layer;
removing the first carrier to expose the first redistribution layer; and
forming second connection terminals on one side of the first redistribution layer away from the first semiconductor device.
